(19) United States
(12) Patent Application Publication
(10) Pub. No.: US 2023/0007785 A1
(43) Pub. Date: Jan. 5, 2023

(54) METHOD FOR PRODUCING WIRING CIRCUIT BOARD

(71) Applicant: NITTO DENKO CORPORATION, Osaka (JP)

(72) Inventors: Kenya TAKIMOTO, Osaka (JP); Naoki SHIBATA, Osaka (JP); Hayato TAKAKURA, Osaka (JP)

(73) Assignee: NITTO DENKO CORPORATION, Osaka (JP)

(21) Appl. No.: 17/779,890

(22) PCT Filed: Nov. 5, 2020
(86) PCT No.: PCT/JP2020/041318

§ 371 Date: May 25, 2022

(30) Foreign Application Priority Data
Dec. 4, 2019 (JP) 2019-219260

(51) Int. Cl. H05K 3/28

(52) U.S. Cl. CPC H05K 3/28; H05K 2203/1383; H05K 2203/1545

(57) ABSTRACT

A method for producing a wiring circuit board includes a first step, a second step, and a third step. In the first step, while a work film which is a long metal substrate having a first surface and a second surface opposite to the first surface is fed and wound by a roll-to-roll method, a composition containing a photosensitive resin is applied onto the first surface to form an insulating film, and a protective film is interposed between the second surface and the insulating film of the work film in being wound. In the second step, while the work film having undergone the first step is fed and wound by the roll-to-roll method, the protective film is peeled from the insulating film, and the insulating film is subjected to light exposure treatment to be formed with a latent image pattern. In a third step, the insulating film having undergone the second step is subjected to development treatment to be patterned.

### TECHNICAL FIELD

The present invention relates to a method for producing a wiring circuit board.

### BACKGROUND ART

A wiring circuit board is produced by forming conductive portions such as wirings and various insulating layers on a substrate in lamination. The conductive portions and the insulating layer are pattern-formed by, for example, a photolithography method. Each step included in the production process of such a wiring circuit board may be carried out in a so-called roll-to-roll method in order to realize a high production efficiency. The technique relating to a method for producing a wiring circuit board in the roll-to-roll method is, for example, described in Patent Document 1 below.

### CITATION LIST

### Patent Document

Patent Document 1: Japanese Unexamined Patent Publication No. 2005-85944

### SUMMARY OF THE INVENTION

### Problem to be Solved by the Invention

When a substrate to be provided to a production line of a wiring circuit board in a roll-to-roll method is a sheet-shaped metal substrate, foreign matters may be attached to the surface of the substrate. Depending on the type of metal constituting the metal substrate, and a production process of the substrate, the foreign matters may be numerous. When the wiring circuit board is produced in the roll-to-roll method using such a metal substrate, in the metal substrate, the surface (processing surface) to which processing is subjected in a predetermined step (step P), and the rear surface accompanied with foreign matters due to the metal substrate surface being exposed on the opposite side to the processing surface are overlapped, in a state where the metal substrate is wound up and takes the form of a roll after the step P. Therefore, the foreign matters are easily transferred from the rear surface onto the processing surface.

When the step P is a step of forming an insulating film to be patterned by a photolithography method (i.e., an insulating film-forming step by application of a photosensitive resin-containing composition onto the metal substrate), in a subsequent exposure step, the insulating film is subjected to light exposure treatment in a state where foreign matters are attached to various portions on the surface of the insulating film on the processing surface-side, and the foreign matter attaching portions in the insulating film are not appropriately exposed to light. The insulating film having undergone such an exposure step may not be appropriately patterned in a subsequent development step. For example, the portion to which the foreign matter is attached in the insulating film during the exposure step is removed in the development step, and a pinhole to which the metal substrate directly below the insulating film faces is formed in the portion of the insulating film. When the wiring is pattern-formed in a region including such a pinhole on the insulating film, a short circuit occurs between the wiring and the metal substrate, and the reliability of the wiring is impaired.

The present invention provides a method for producing a wiring circuit board suitable for ensuring the reliability of a wiring to be formed.

### Means for Solving the Problem

The present invention [1] includes a method for producing a wiring circuit board, the method including a first step of, while feeding and winding a work film which is a long metal substrate having a first surface and a second surface opposite to the first surface by a roll-to-roll method, applying a composition containing a photosensitive resin onto the first surface to form an insulating film, and interposing a protective film between the second surface and the insulating film of the work film in being wound; a second step of, while feeding and winding the work film having undergone the first step by the roll-to-roll method, peeling the protective film from the insulating film, and subjecting the insulating film to light exposure treatment to be formed with a latent image pattern; and a third step of subjecting the insulating film having undergone the second step to development treatment to be patterned.

In the first step, in the roll-to-roll method, of the present method, as described above, the work film is wound while the protective film is interposed between the insulating film and the second surface of the metal substrate, after forming the insulating film on the first surface of the metal substrate as the work film. Therefore, even when the foreign matter is attached to the second surface of the metal substrate to be subjected to the first step, it is possible to suppress the transfer of the foreign matter from the second surface to the insulating film in the work film in a roll form after the first step. In the second step of the present method, in the roll-to-roll method, since the insulating film in which the transfer of the foreign matter from the second surface is suppressed is subjected to light exposure treatment after peeling the protective film from the insulating film, the insulating film can be appropriately subjected to light exposure treatment in a predetermined pattern to be formed with the latent image pattern, and in the subsequent third step, the insulating film can be appropriately patterned by the development treatment.

According to the present method, it is possible to pattern the insulating film while suppressing the formation of a pinhole caused by the attachment of the foreign matter in the insulating film. Therefore, for example, when the wiring is pattern-formed on the insulating film, it is possible to suppress an occurrence of a short circuit between the wiring and the metal substrate. Therefore, the present method is suitable for ensuring the reliability of the wiring to be formed.

The present invention [2] includes the method for producing a wiring circuit board described in the above-described [1], further including a fourth step of forming a wiring on the insulating film having undergone the third step.

In such a configuration, it is possible to suppress an occurrence of a short circuit between the wiring formed on the insulating film in the fourth step and the metal substrate. Therefore, such a configuration is suitable for ensuring the reliability of the wiring to be formed.

The present invention [3] includes the method for producing a wiring circuit board described in the above-described [1], wherein the work film in the first step further includes a base insulating layer on the first surface of the metal substrate and a wiring on the base insulating layer; and the insulating film formed in the first step covers, as a cover insulating layer, the base insulating layer and the wiring on the first surface of the metal substrate.

According to such a configuration, it is possible to pattern the insulating film, while suppressing the formation of a pinhole caused by the attachment of the foreign matter in the insulating film covering the wiring. Therefore, it is possible to appropriately cover the wiring by the insulating film in which the formation of the pinhole is suppressed. Thus, such a configuration is suitable for ensuring the reliability of the wiring to be formed.

The present invention [4] includes the method for producing a wiring circuit board described in any one of the above-described [1] to [3], wherein the metal substrate is made of Cu or Cu alloy.

The metal substrate made of Cu or Cu alloy such as rolled copper foil often has a foreign matter attached to its surface. According to the present method, it is possible to suppress the attachment of the foreign matter to the insulating film as described above, even in the use of such a metal substrate.

The present invention [5] includes the method for producing a wiring circuit board described in any one of the above-described [1] to [4], wherein the protective film is a polypropylene film.

Such a configuration is suitable for ensuring the followability of the protective film, which is wound along with the work film in the first step, to the work film, and suppressing the occurrence of wrinkles in the protective film.

The present invention [6] includes the method for producing a wiring circuit board described in any one of the above-described [1] to [5], wherein the protective film has a thickness of 30 μm or more and 70 μm or less.

Such a configuration is suitable for ensuring the followability of the protective film, which is wound along with the work film in the first step, to the work film, and suppressing the occurrence of wrinkles in the protective film.

The present invention [7] includes the method for producing a wiring circuit board described in any one of the above-described [1] to [6], wherein the photosensitive resin is a polyimide resin.

Such a configuration is suitable for forming the insulating film having excellent insulation and heat resistance from the above-described composition as, for example, a base insulating layer and a cover insulating layer in the wiring circuit board.

### BRIEF DESCRIPTION OF THE DRAWINGS

FIGS. 1A-1D shows a part of steps in one embodiment of a method for producing a wiring circuit board of the present invention:

FIG. 1A illustrating a preparation step,

FIG. 1B illustrating a first insulating film-forming step,

FIG. 1C illustrating a first exposure step, and

FIG. 1D illustrating a first development step.

FIG. 2A-2D shows steps following the steps shown in FIGS. 1A-1D:

FIG. 2A illustrating a first curing step,

FIG. 2B illustrating a seed layer-forming step,

FIG. 2C illustrating a resist film-forming step, and

FIG. 2D illustrating a second exposure step.

FIGS. 3A-3D shows steps following the steps shown in FIGS. 2A-2D:

FIG. 3A illustrating a second development step,

FIG. 3B illustrating a conductive portion-forming step,

FIG. 3C illustrating a resist pattern removal step, and

FIG. 3D illustrating a seed layer partially removal step.

FIGS. 4A-4D shows steps following the steps shown in FIGS. 3A-3D:

FIG. 4A illustrating a second insulating film-forming step,

FIG. 4B illustrating a third exposure step,

FIG. 4C illustrating a third development step, and

FIG. 4D illustrating a second curing step.

FIG. 5 shows a form of a roll-to-roll method in the step (first insulating film-forming step) shown in FIG. 1B.

FIG. 6 shows a form of a roll-to-roll method in the step (first exposure step) shown in FIG. 1C.

FIG. 7 shows a form of a roll-to-roll method in the step (second insulating film-forming step) shown in FIG. 4A.

FIG. 8 shows a form of a roll-to-roll method in the step (third exposure step) shown in FIG. 4B.

### DESCRIPTION OF EMBODIMENTS

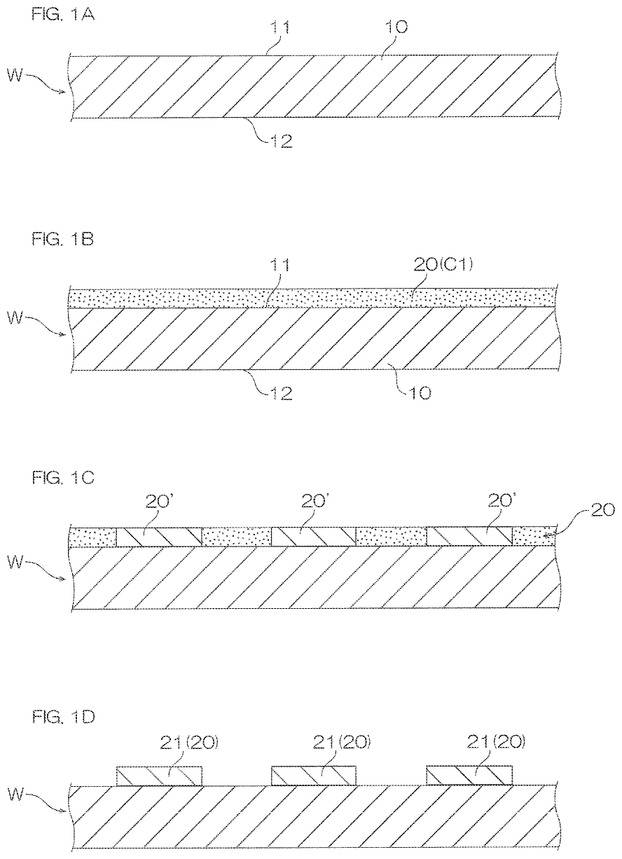

FIGS. 1 to 8 show one embodiment of a method for producing a wiring circuit board of the present invention. The present method is, for example, a method for producing a wiring circuit board X to be described later by subjecting a work film W to various treatment and processing in a roll-to-roll method.

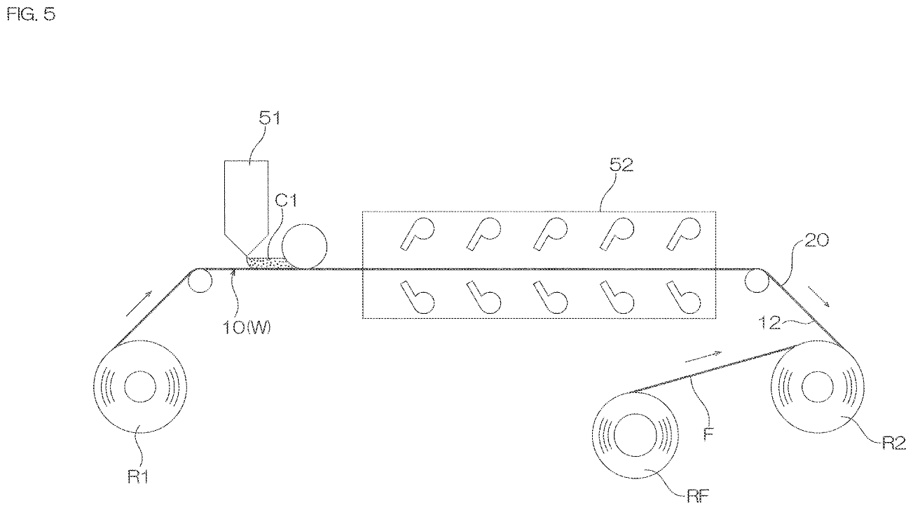

In the present production method, first, as shown in FIG. 1A, a long metal substrate 10 is prepared as the work film W (preparation step). The metal substrate 10 has a first surface 11 which is to be subjected processing, and a second surface 12 at the opposite side thereto. Examples of a constituent material of the metal substrate 10 include Cu, Cu alloy, stainless steel, and 42-alloy. From the viewpoint of easy processing, preferably, Cu and Cu alloy are used. The metal substrate 10 has a thickness of, for example, 10 μm or more, preferably 15 μm or more, and for example, 500 μm or less, preferably 300 μm or less. In the present step, such a metal substrate 10 is prepared, as the work film W, in a roll R1 form shown in FIG. 5.

The first surface 11 of the metal substrate 10 is subjected to cleaning treatment if necessary. An example of the cleaning treatment includes plasma cleaning.

In the present production method, next, as shown in FIG. 1B, a composition (varnish) C1 containing a photosensitive resin is applied onto the metal substrate 10, thereby forming an insulating film 20 as a base insulating layer (first insulating film-forming step, one form of the first step in the present invention). Specifically, as shown in FIG. 1B, the composition C1 is applied from a coater 51 onto the first surface 11 of the metal substrate 10, while, as shown in FIG. 5, the metal substrate 10 which is the work film W is fed from the roll R1 to be wound around a roll R2 by the roll-to-roll method. The applied composition C1 passes through a drying furnace 52 to be dried, thereby forming the insulating film 20 (not shown in FIG. 5). The insulating film 20 is in an uncured state, and a foreign matter is easily attached to its surface. Examples of the photosensitive resin include synthetic resins such as polyimide resins, polyamidimide resins, acrylic resins, polyether nitrile resins, polyether sulfone resins, polyethylene terephthalate resins, polyethylene naphthalate resins, and polyvinyl chloride resins. From the viewpoint of insulation and heat resistance of the insulating film 20 to be formed, preferably, a polyimide resin is used. The insulating film 20 has a thickness of, for example, 3 μm or more, preferably 5 μm or more, and for example, 50 μm or less, preferably 30 μm or less.

In the present step, as shown in FIG. 5, in the work film W which is wound around the roll R2 after the formation of the insulating film 20, a protective film F is interposed between the insulating film 20 of the work film W which is already wound, and the second surface 12 of the work film W to be wound next. The protective film F is fed from a separately prepared roll RF to space between the insulating film 20 and the second surface 12. Examples of the protective film F include polypropylene (PP) films, polyethylene (PE) films, polyethylene terephthalate (PET) films, and polyethylene naphthalate (PEN) films. Preferably, a polypropylene film is used. Further, the protective film F has a thickness of preferably 30 μm or more, more preferably 35 μm or more, and preferably 70 μm or less, more preferably 65 μm or less.

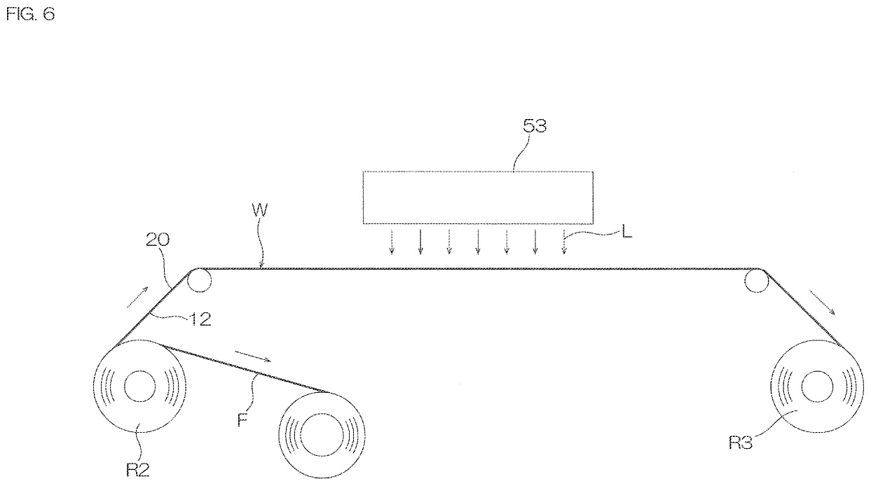

In the present production method, next, as shown in FIG. 1C, the insulating film 20 is subjected to light exposure treatment, thereby forming a latent image pattern 20′ (first exposure step, one form of the second step in the present invention). Specifically, as shown in FIG. 6, the protective film F is peeled from the insulating film 20 (not shown in FIG. 6), and the insulating film 20 is subjected to light exposure treatment with an exposure device 53, while the work film W having undergone the first insulating film-forming step is fed from the roll R2 to be wound around a roll R3 by the roll-to-roll method. Then, as shown in FIG. 1C, the latent image pattern 20′ is formed in the insulating film 20. In the light exposure treatment, for example, an ultraviolet ray L is applied to the insulating film 20 via a mask (not shown) having an opening portion in a predetermined pattern.

Next, as shown in FIG. 1D, the insulating film 20 is subjected to development treatment to be patterned (first development step, one form of the third step in the present invention). Specifically, the insulating film 20 having undergone the first exposure step is subjected to development treatment to be patterned, while the work film W is fed and wound by the roll-to-roll method. Thus, an insulating layer 21 in a predetermined pattern is formed. In the development treatment, for example, the work film W having the insulating film 20 is immersed in a bath of a predetermined developing solution to pass through the bath. As the developing solution, for example, an alkali solution such as sodium hydroxide and potassium hydroxide can be used.

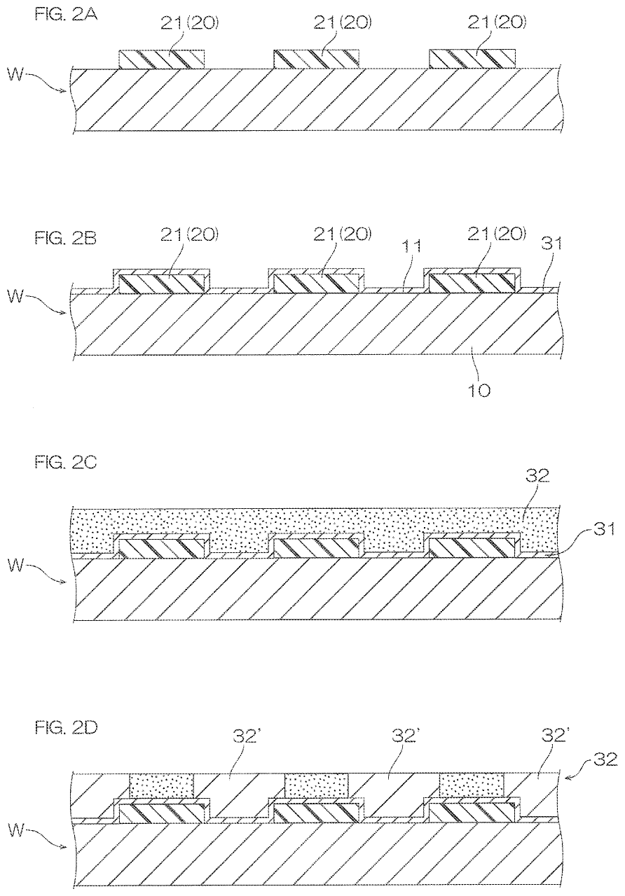

Next, as shown in FIG. 2A, the insulating layer 21 is cured by heating (first curing step). The heating temperature is, for example, 200° C. to 450° C., and the heating time is, for example, 0.5 to 48 hours. The cured insulating layer 21 functions as a base insulating layer on which a conductive portion 34 to be described later is formed in lamination in a wiring circuit board to be produced.

Next, as shown in FIG. 2B, a seed layer 31 is formed on the work film W (seed layer-forming step). The seed layer 31 is an element which functions as a current-carrying layer in an electroplating method to be described later, and is formed so as to cover the first surface 11 of the metal substrate 10 and the insulating layer 21 thereon in the work film W. Examples of a constituent material of the seed layer 31 include Cr, Cu, Ni, Ti, and alloys of these. The seed layer 31 may have a single layer structure, or a multilayer structure of two or more layers. The seed layer 31 has a thickness of, for example, 10 to 1000 nm. Examples of a method for forming the seed layer 31 include a sputtering method, an electrolytic plating method, and an electroless plating method, and preferably, a sputtering method is used.

Next, as shown in FIG. 2C, a resist film 32 is formed on the work film W (resist film-forming step). For example, a dry film resist having photosensitivity is bonded or attached to the work film W so as to cover the seed layer 31, while the work film W is fed and wound by the roll-to-roll method, thereby forming the resist film 32. The resist film 32 has a thickness of, for example, 5 μm or more, and for example, 100 μm or less.

In the present production method, next, as shown in FIG. 2D, the resist film 32 is subjected to light exposure treatment, thereby forming a latent image pattern 32′ (second exposure step). In the light exposure treatment, for example, the resist film 32 is irradiated with ultraviolet rays through a mask having opening portions in a predetermined pattern.

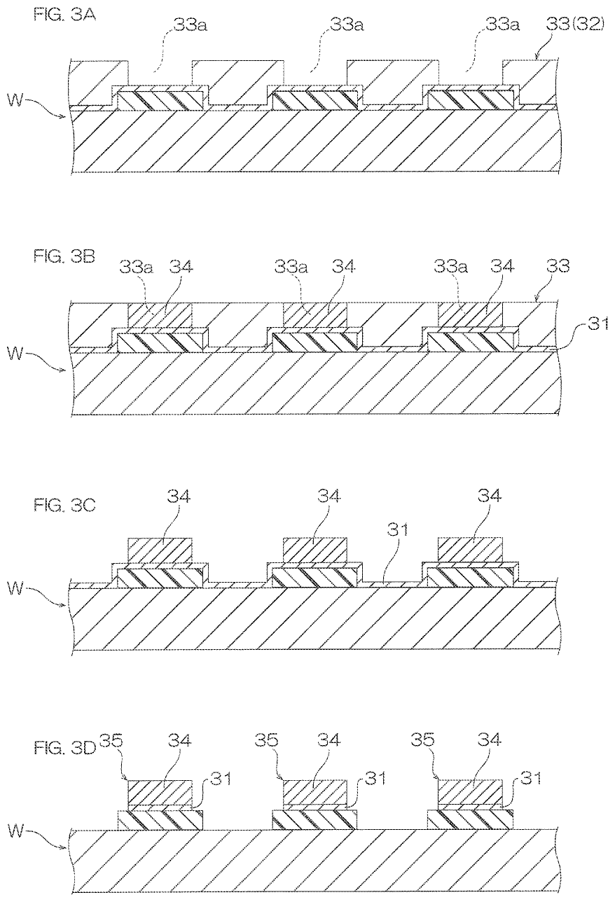

Next, as shown in FIG. 3A, the resist film 32 is subjected to development treatment to be patterned, thereby forming a resist pattern 33 having predetermined opening portions 33a (second development step). The development treatment can be carried out by, for example, a spray etching method. Otherwise, in the development treatment, the work film W having the resist film 32 may be immersed in a bath of a predetermined developing solution to pass through the bath.

Next, as shown in FIG. 3B, the conductive portion 34 is formed (conductive portion-forming step). Specifically, a metal material is grown on the seed layer 31 in a region within the opening portion 33a of the resist pattern 33 by an electroplating method. As the metal material, preferably, copper is used. The conductive portion 34 to be formed has a thickness of, for example, 1 μm or more, and for example, 50 μm or less.

Next, as shown in FIG. 3C, the resist pattern 33 is removed from the work film W by, for example, etching (resist pattern removal step).

Next, as shown in FIG. 3D, in the seed layer 31, a portion exposed by the above-described resist pattern removal is removed by, for example, etching (seed layer partially removal step). Thus, a wiring 35 including the seed layer 31 and the conductive portion 34 thereon is formed (a series of steps from the above-described seed layer-forming step shown in FIG. 2B to the present step are one example of the fourth step in the present invention).

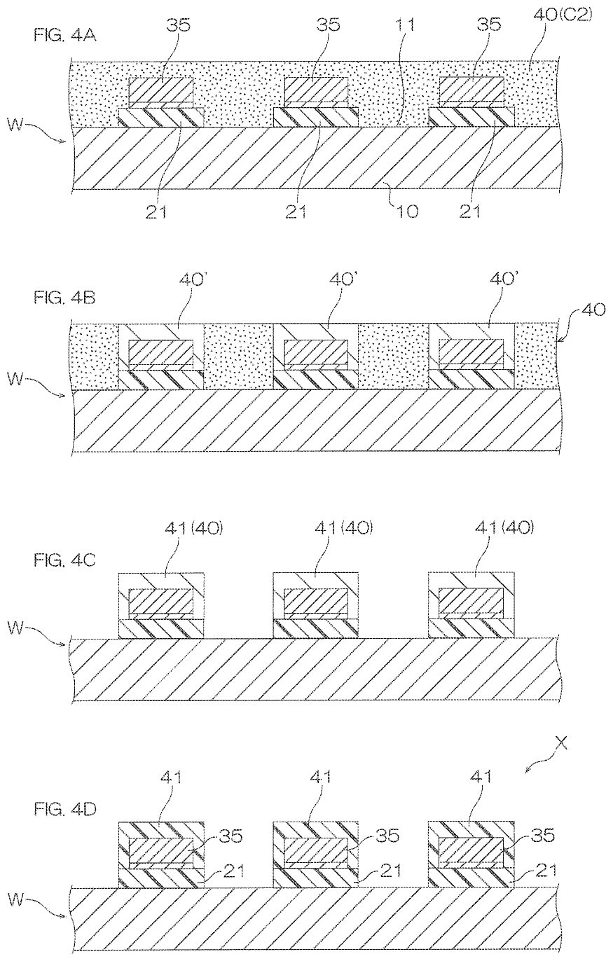

Next, as shown in FIG. 4A, a composition containing a photosensitive resin is applied onto the work film W, thereby forming an insulating film 40 as a cover insulating layer (second insulating film-forming step, one form of the first step in the present invention). The work film W which is subjected to the present step includes, in addition to the metal substrate 10, the insulating layer 21 on the first surface 11 thereof, and the wiring 35 on the insulating layer 21.

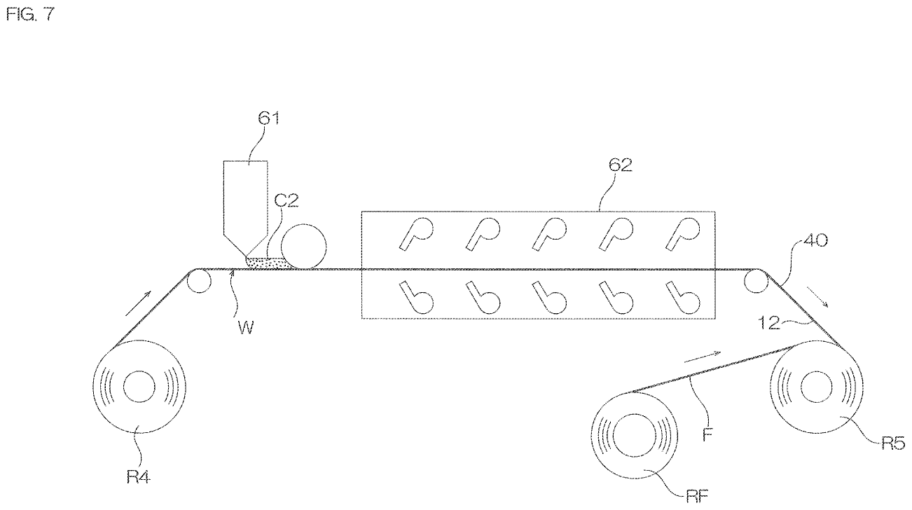

In the present step, specifically, as shown in FIG. 4A, a composition (varnish) C2 is applied from a coater 61 onto the first surface 11 of the metal substrate 10 so as to cover the insulating layer 21 and the wiring 35, while, as shown in FIG. 7, the work film W is fed from a roll R4 to be wound around a roll R5 by the roll-to-roll method. The applied composition C2 passes through a drying furnace 62 to be dried, thereby forming the insulating film 40 (not shown in FIG. 7). The insulating film 40 covers the insulating layer 21 and the wiring 35 on the first surface 11 of the metal substrate 10. The insulating film 40 is in an uncured state, and a foreign matter is easily attached to its surface. Examples of the photosensitive resin include synthetic resins such as polyimide resins, polyamidimide resins, acrylic resins, polyether nitrile resins, polyether sulfone resins, polyethylene terephthalate resins, polyethylene naphthalate resins, and polyvinyl chloride resins. From the viewpoint of insulation and heat resistance of the insulating film 40 to be formed, preferably, a polyimide resin is used. The insulating film 40 has a thickness (height from the insulating film 20) of, for example, 2 μm or more, preferably 5 μm or more, and for example, 50 μm or less, preferably 30 μm or less.

In the present step, as shown in FIG. 7, in the work film W which is wound around the roll R5 after the formation of the insulating film 40, the protective film F is interposed between the insulating film 40 of the work film W which is already wound, and the second surface 12 of the work film W to be wound next. The protective film F is fed from the separately prepared roll RF to space between the insulating film 40 and the second surface 12.

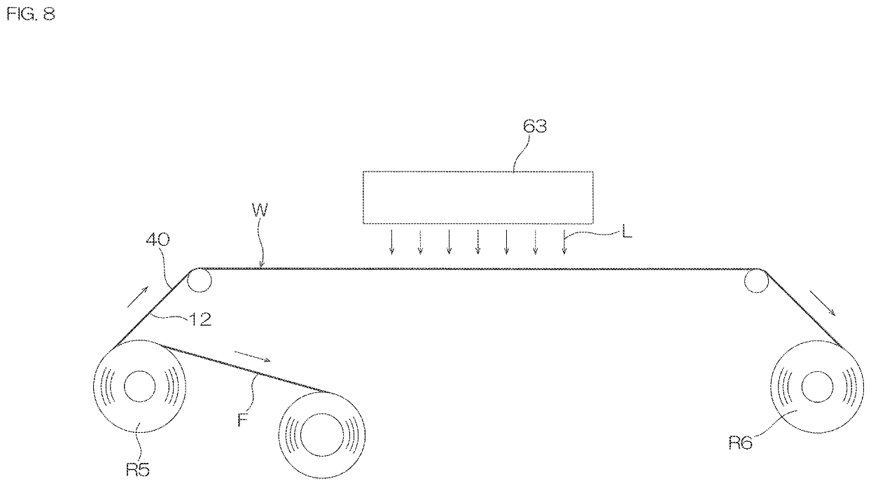

In the present production method, next, as shown in FIG. 4B, the insulating film 40 is subjected to light exposure treatment with an exposure device 63, thereby forming a latent image pattern 40′ (third exposure step, one form of the second step in the present invention). Specifically, as shown in FIG. 8, the protective film F is peeled from the insulating film 40 (not shown in FIG. 8), and the insulating film 40 is subjected to light exposure treatment, while the work film W having undergone the second insulating film-forming step is fed from the roll R5 to be wound around a roll R6 by the roll-to-roll method. Then, as shown in FIG. 4B, the latent image pattern 40′ is formed in the insulating film 40. In the light exposure treatment, for example, the insulating film 40 is irradiated with ultraviolet rays through a mask (not shown) having opening portions in a predetermined pattern.

Next, as shown in FIG. 4C, the insulating film 40 is subjected to development treatment to be patterned (third development step, one form of the third step in the present invention). Specifically, the insulating film 40 having undergone the third exposure step is subjected to development treatment to be patterned, while the work film W is fed and wound by the roll-to-roll method. Thus, an insulating layer 41 is formed. In the development treatment, for example, the work film W having the insulating film 40 is immersed in a bath of a predetermined developing solution to pass through the bath. As the developing solution, for example, an alkali solution such as sodium hydroxide and potassium hydroxide can be used.

Next, as shown in FIG. 4D, the insulating layer 41 is cured by heating (second curing step). The heating temperature is, for example, 200° C. to 450° C., and the heating time is, for example, 0.5 to 48 hours. The cured insulating layer 41 functions as a cover insulating layer covering the wiring 35 in a wiring circuit board to be produced.

Thereafter, the metal substrate 10 may be processed so as to have an outer shape in a predetermined pattern.

As described above, the wiring circuit board X is produced.

In the above-described first insulating film-forming step with reference to FIGS. 1B and 5, in the roll-to-roll method, the work film W is wound while the protective film F is interposed between the insulating film 20 and the second surface 12 of the metal substrate 10 after forming the insulating film 20 on the first surface 11 of the metal substrate 10 as the work film W. Therefore, even when the foreign matter is attached to the second surface 12 of the metal substrate 10 to be subjected to the first insulating film-forming step, it is possible to suppress the transfer of the foreign matter from the second surface 12 to the insulating film 20 in the work film W in a roll R2 form after the first insulating film-forming step. In the above-described first exposure step with reference to FIGS. 1C and 6, in the roll-to-roll method, since the insulating film 20 in which the transfer of the foreign matter from the second surface 12 is suppressed is subjected to light exposure treatment after peeling the protective film F from the insulating film 20, the insulating film 20 can be appropriately subjected to light exposure treatment in a predetermined pattern to be formed with the latent image pattern 20′, and in the subsequent first development step shown in FIG. 1D, the insulating film 20 can be appropriately patterned by the development treatment.

According to the present method, it is possible to pattern the insulating film 20 while suppressing the formation of a pinhole caused by the attachment of the foreign matter in the insulating film 20. Therefore, it is possible to suppress an occurrence of a short circuit between the above-described wiring 35 formed on the insulating film 20 and the metal substrate 10. Therefore, the present method is suitable for ensuring the reliability of the wiring 35 to be formed.

In the above-described second insulating film-forming step with reference to FIGS. 4A and 7, in the roll-to-roll method, the work film W is wound while the protective film F is interposed between the insulating film 40 and the second surface 12 of the metal substrate 10 after forming the insulating film 40 on the work film W. Therefore, even when the foreign matter is attached to the second surface 12 of the metal substrate 10 in the work film W to be subjected to the second insulating film-forming step, it is possible to suppress the transfer of the foreign matter from the second surface 12 to the insulating film 40 in the work film W in a roll R5 form after the second insulating film-forming step. In the above-described third exposure step with reference to FIGS. 4B and 8, in the roll-to-roll method, since the insulating film 40 in which the transfer of the foreign matter from the second surface 12 is suppressed is subjected to light exposure treatment after peeling the protective film F from the insulating film 40, the insulating film 40 can be appropriately subjected to light exposure treatment in a predetermined pattern to be formed with the latent image pattern 40′, and in the subsequent third development step shown in FIG. 4C, the insulating film 40 can be appropriately patterned by the development treatment.

According to the present method, it is possible to pattern the insulating film 40 while suppressing the formation of a pinhole caused by the attachment of the foreign matter in the insulating film 40. Therefore, it is possible to appropriately cover the above-described wiring 35 by the insulating film 40 in which the formation of the pinhole is suppressed. Thus, in this respect, the present method is suitable for ensuring the reliability of the wiring 35 to be formed.

The metal substrate 10 in the present method is, as described above, preferably made of Cu or Cu alloy. The metal substrate made of Cu or Cu alloy such as rolled copper foil often has a foreign matter attached to its surface. According to the present method, as described above, it is possible to suppress the attachment of the foreign matter to the insulating films 20 and 40 even in the use of such a metal substrate as the metal substrate 10.

The protective film F in the present method is, as described above, preferably a polypropylene film. Such a configuration is suitable for suppressing the occurrence of wrinkles in the protective film F which is wound along with the work film W in the above-described first insulating film-forming step and second insulating film-forming step.

Further, as described above, the protective film has a thickness of preferably 30 μm or more, more preferably 35 μm or more, and preferably 70 μm or less, more preferably 65 μm or less. Such a configuration is suitable for suppressing the occurrence of wrinkles in the protective film F which is wound along with the work film W in the above-described first insulating film-forming step and second insulating film-forming step.

As described above, the present method is suitable for efficiently producing the wiring circuit board X in the roll-to-roll method, and for ensuring the reliability of the wiring 35 to be formed.

In the present method, even in the steps other than the above-described steps with reference to FIGS. 1B and 4A, the attachment of the above-described foreign matter to the processing surface of the work film W may be suppressed by interposing the protective film F and winding the work film W around a roll.

### EXAMPLES

### Examples 1 to 7

Each of the steps described above with reference to FIGS. 1A to 3D, 5, and 6 was carried out as described below to form the insulating layer 21 and the wiring 35 thereon in predetermined patterns on the metal substrate 10, thereby fabricating the wiring circuit boards of Examples 1 to 7 (for each Example, the plurality of wiring circuit boards were fabricated over a region of a total length of 100 meters in each of the work films W of 20 rolls).

In the preparation step shown in FIG. 1A, a rolled long copper foil (thickness of 10 μm) was prepared as the metal substrate 10.

In the first insulating film-forming step shown in FIG. 1B, the composition C1 containing a predetermined polyimide resin, as a photosensitive resin, was applied onto the metal substrate 10, thereby forming the insulating film 20. Specifically, as shown in FIG. 5, the composition (varnish) C1 was applied onto the first surface 11 of the metal substrate 10 which was the work film W, while the metal substrate 10 was fed from the roll R1 to be wound around the roll R2 in the roll-to-roll method. The applied composition C1 was dried, thereby forming the insulating film 20 (thickness of 10 μm). In the present step, in the work film W in being wound, the protective film F was interposed between the second surface 12 and the insulating film 20. As the protective film F, a polypropylene (PP) film having a thickness of 40 μm (melting temperature of 170° C.) was used for Example 1, a PP film having a thickness of 60 μm (melting temperature of 170° C.) was used for Example 2, a polyethylene terephthalate (PET) film having a thickness of 38 μm (melting temperature of 260° C.) was used for Example 3, a PET film having a thickness of 50 μm (melting temperature of 260° C.) was used for Example 4, a PET film having a thickness of 125 μm (melting temperature of 260° C.) was used for Example 5, a polyethylene naphthalate (PEN) film having a thickness of 50 μm (melting temperature of 265° C.) was used for Example 6, and a PE film having a thickness of 50 μm (melting temperature of 135° C.) was used for Example 7.

In the first exposure step shown in FIG. 1C, the insulating film 20 was subjected to light exposure treatment, thereby forming the latent image pattern 20′. Specifically, as shown in FIG. 6, the protective film F was peeled from the insulating film 20 (not shown in FIG. 6), and then, the insulating film 20 was subjected to light exposure treatment, while the work film W was fed from the roll R2 to be wound around the roll R3 in the roll-to-roll method. Then, as shown in FIG. 1C, the latent image pattern 20′ was formed in the insulating film 20. In the light exposure treatment, the insulating film 20 was irradiated with an ultraviolet ray having a wavelength of 365 nm through a mask having opening portions in a predetermined pattern.

In the first development step shown in FIG. 1D, the insulating film 20 having undergone the first exposure step was subjected to development treatment to be patterned, while the work film W was fed and wound in the roll-to-roll method. Thus, the insulating layer 21 in a predetermined pattern was formed. In the development treatment, a sodium hydroxide/ethanol amine solution was used as a developing solution.

In the first curing step shown in FIG. 2A, the insulating layer 21 was cured by heating. The heating temperature was 400° C., and the heating time was 2 hours.

In the seed layer-forming step shown in FIG. 2B, the seed layer 31 was formed in lamination so that the total thickness of a Cr film and a Cu film was 100 nm by a sputtering method so as to cover the first surface 11 of the metal substrate 10 and the insulating layer 21 thereon of the work film W.

In the resist film-forming step shown in FIG. 2C, a dry film resist having photosensitivity was bonded to the work film W so as to cover the seed layer 31, while the work film W was fed and wound in the roll-to-roll method, thereby forming the resist film 32.

In the second exposure step shown in FIG. 2D, the resist film 32 was subjected to light exposure treatment, thereby forming the latent image pattern 32′. In the light exposure treatment, for example, the resist film 32 was irradiated with an ultraviolet ray having a wavelength of 365 nm through a mask having opening portions in a predetermined pattern.

In the second development step shown in FIG. 3A, the resist film 32 was subjected to development treatment to be patterned, thereby forming the resist pattern 33 having the predetermined opening portion 33a. In the development treatment, a sodium carbonate solution was used as a developing solution.

In the conductive portion-forming step shown in FIG. 3B, a copper wiring having a thickness of 10 μm was formed in the opening portion 33a of the resist pattern 33 by an electroplating method using the seed layer 31 as a current-carrying layer.

In the resist pattern removal step shown in FIG. 3C, the resist pattern 33 was removed from the work film W by etching using a sodium hydroxide solution as an etchant.

In the seed layer partially removal step shown in FIG. 3D, a portion exposed in the seed layer 31 by the above-described resist pattern removal was removed by etching using a cerium (IV) ammonium nitrate solution as an etchant.

### Comparative Example 1

A wiring circuit board of Comparative Example 1 was fabricated in the same manner as the wiring circuit boards of Examples 1 to 7, except that the protective film F was not used.

<Defective Ratio>

In each of the wiring circuit boards of Examples 1 to 7 and Comparative Example 1, it was examined whether a short circuit occurred between each of the formed wirings and the metal substrate. Then, a ratio of the number of wirings having a short circuit between the wiring and the metal substrate with respect to the total number of the formed wirings was calculated as a defective ratio (%). For the defective ratio, a case of less than 10% was evaluated as “Excellent”, and a case of 10% or more was evaluated as “Bad”. The results are shown in Table 1.

<Heat Resistance>

For the heat resistance of the protective film used in the production process of each of the wiring circuit boards of Examples 1 to 7, a case where the melting temperature of the protective film was 140° C. or more was evaluated as “Excellent”, and a case where the melting temperature of the protective film was less than 140° C. was evaluated as “Bad”. The results are shown in Table 1.

<Suppression of Wrinkles>

For each of the wiring circuit boards of Examples 1 to 7, a degree of suppression of wrinkles was examined Specifically, for the degree of suppression of wrinkles, among the 20 rolls of work film of each Example, where each roll had a wiring circuit board-forming region of the total length of 100 meters, a case where a ratio of the number of work films having wrinkles was less than 10% was evaluated as “Excellent”, a case where the ratio thereof was 10% or more and less than 25% was evaluated as “Good”, and a case where the ratio thereof was 25% or more was evaluated as “Bad”. The results are shown in Table 1.

TABLE 1

| | Protective Film | | | | |
|---|---|---|---|---|---|
| | | Thickness | Defective | Heat | Suppression |
| | Material | (μm) | Ratio | Resistance | of Wrinkles |
| Ex. 1 | PP | 40 | Excellent | Excellent | Excellent |
| Ex. 2 | PP | 60 | Excellent | Excellent | Excellent |
| Ex. 3 | PET | 38 | Excellent | Excellent | Good |
| Ex. 4 | PET | 50 | Excellent | Excellent | Good |
| Ex. 5 | PET | 125 | Excellent | Excellent | Bad |
| Ex. 6 | PEN | 50 | Excellent | Excellent | Good |
| Ex. 7 | PE | 50 | Excellent | Bad | Excellent |
| Comparative | — | — | Bad | — | — |
| Ex. 1 | | | | | |

### INDUSTRIAL APPLICATION

The method for producing a wiring circuit board of the present invention may be applied to a method for producing various flexible wiring circuit boards.

### DESCRIPTION OF REFERENCE NUMERALS

X Wiring circuit board
W Work film
F Protective film
Metal substrate
First surface
Second surface
C1, C2 Composition
20, 40 Insulating film
20′, 40′ Latent image pattern
21, 41 Insulating layer
Seed layer
Resist film
Resist pattern
33a Opening portion
Wiring
R1 to R6 Roll

1. A method for producing a wiring circuit board, the method comprising:
a first step of, while feeding and winding a work film which is a long metal substrate having a first surface and a second surface opposite to the first surface by a roll-to-roll method, applying a composition containing a photosensitive resin onto the first surface to form an insulating film, and interposing a protective film between the second surface and the insulating film of the work film in being wound;
a second step of, while feeding and winding the work film having undergone the first step by the roll-to-roll method, peeling the protective film from the insulating film, and subjecting the insulating film to light exposure treatment to be formed with a latent image pattern; and
a third step of subjecting the insulating film having undergone the second step to development treatment to be patterned.

2. The method for producing a wiring circuit board according to claim 1, further comprising
a fourth step of forming a wiring on the insulating film having undergone the third step.

3. The method for producing a wiring circuit board according to claim 1, wherein
the work film in the first step further includes a base insulating layer on the first surface of the metal substrate and a wiring on the base insulating layer; and
the insulating film formed in the first step covers, as a cover insulating layer, the base insulating layer and the wiring on the first surface of the metal substrate.

4. The method for producing a wiring circuit board according to claim 1, wherein the metal substrate is made of Cu or Cu alloy.

5. The method for producing a wiring circuit board according to claim 1, wherein the protective film is a polypropylene film.

6. The method for producing a wiring circuit board according to claim 1, wherein the protective film has a thickness of 30 μm or more and 70 μm or less.

7. The method for producing a wiring circuit board according to claim 1, wherein the photosensitive resin is a polyimide resin.
